(19) United States
(12) Patent Application Publication
(10) Pub. No.: US 2005/0269943 A1
(43) Pub. Date: Dec. 8, 2005

(54) Protected organic electronic devices and methods for making the same

(76) Inventors: Michael Hack, Lambertville, NJ (US); Anna Chwang, Princeton, NJ (US); Jeffrey Alan Silvernail, Yardley, PA (US)

Correspondence Address: MAYER, FORTKORT & WILLIAMS, PC, 251 NORTH AVENUE WEST, 2ND FLOOR, WESTFIELD, NJ, 07090, US

(21) Appl. No.: 10/861,234

(22) Filed: Jun. 4, 2004

(51) Int. Cl. H05B 33/00

(52) U.S. Cl. 313/504; 313/512

(57) ABSTRACT

The present invention relates to structures and components for protecting organic light emitting diodes from environmental elements such as moisture and oxygen. According to a first aspect of the invention, top-emitting, high-resolution, OLED structures are provided which include a metal foil substrate; a planarization layer disposed over the metal foil substrate; an OLED stack (which includes lower and upper electrodes as well as an organic region disposed between the electrodes) disposed over the planarization layer; and a multilayer barrier region disposed over the OLED stack. A second aspect of the invention is directed to flexible, top emitting OLED structures which include the following: thin substrate region (i.e., a substrate having a thickness that is less than 200 microns); an OLED stack disposed over the flexible substrate region; a transparent upper barrier region that cooperates with the flexible substrate region to encapsulate the OLED stack, thereby protecting it from outside species such as water or oxygen; and a polymeric reinforcement layer which has a Young's Modulus ranging from about 0.3 to 7 GPa, which is disposed (i) below the substrate region, (ii) above the upper barrier region (in which case it is transparent), or (iii) both below the substrate region and above the upper barrier region.

### FIELD OF THE INVENTION

The present invention relates to various novel organic light emitting diode (OLED) structures.

### BACKGROUND OF THE INVENTION

Organic light emitting diodes (OLEDs) are becoming increasingly important from an economic standpoint. For example, OLEDs are potential candidates for a wide variety of virtual- and direct-view type displays, such as lap-top computers, televisions, digital watches, telephones, pagers, cellular telephones, calculators and the like. Unlike inorganic semiconductor light emitting devices, organic light emitting devices are generally simple and are relatively easy and inexpensive to fabricate. Also, OLEDs readily lend themselves to applications requiring a wide variety of colors and to large-area device applications.

In general, two-dimensional OLED arrays for imaging applications are known in the art, and include a plurality of pixels arranged in rows and columns. FIG. 1A is a simplified schematic representation (cross-sectional view) of an OLED structure of the prior art. The OLED structure shown includes an OLED stack 15, which in this simplified case is a single pixel consisting of a lower electrode such as anode 12, an organic region 14 over the anode 12, and an upper electrode such as cathode 16 over the organic region 14. The OLED stack 15 is disposed on a substrate 10. The OLED stack 15 is protected by a cover 20, which is attached to the substrate 10 via adhesive 25.

Traditionally, light from the organic region 14 of an OLED stack 15 is passed downward through the substrate 10. In such a “bottom-emitting” configuration, the substrate 10 and the anode 12 are formed of transparent materials. The cathode 16 and cover 20 (i.e., barrier), on the other hand, need not be transparent in this configuration.

Other OLED architectures are also known in the art, including “top-emitting” OLEDs and transparent OLEDs. For top-emitting OLEDs, light from the organic region 14 is transmitted upward through cover 20. Hence, the substrate 10 can be formed of opaque material, if desired, while the cover 20 is transparent. Moreover, in top-emitting configurations based on a design like that illustrated in FIG. 1A, a transparent material is used for the cathode 16, while the anode 12 need not be transparent.

For transparent OLEDs, in which light is emitted out of both the top and bottom of the device, the substrate 10, anode 12, cathode 16 and cover 20 are all transparent.

Structures are also known in which the positions of the anode 12 and cathode 16 in FIG. 1A are reversed as illustrated in FIG. 1B. Such devices are sometimes referred to as “inverted OLEDs.”

In forming an OLED device, a layer of low work function metal is typically utilized as the cathode to ensure efficient electron injection and low operating voltages. Low work function metals, however, are chemically reactive. Consequently, exposure to and subsequent reaction with oxygen and moisture can severely limit the lifetime of an OLED device. Moisture and oxygen are also known to produce other deleterious effects in OLEDs, for instance, reactions with the organic materials themselves. For example, moisture and oxygen are known in the art to increase “dark spots” and pixel shrinkage in OLEDs. In response to these issues, sensitive OLED components have been encapsulated using a variety of techniques.

### SUMMARY OF THE INVENTION

The present invention relates to various novel OLED structures.

According to a first aspect of the invention, top-emitting, high-resolution, OLED structures are provided which include a metal foil substrate and a planarization layer disposed over the metal foil substrate. Metal foils have a number of desirable properties, including high strength and resistance to shrinkage and distortion, which make them ideal as substrates for the formation of high resolution displays. In addition to a planarized metal foil substrate, the top-emitting, high-resolution, OLED structures of this first aspect of the invention also include an OLED stack (which includes lower and upper electrodes as well as an organic region disposed between the electrodes) disposed over the planarization layer; and a multilayer barrier region disposed over the OLED stack.

A second aspect of the invention is directed to flexible, top emitting OLED structures which include the following: (a) thin substrate region (i.e., a substrate having a thickness that is less than 200 microns), (b) an OLED stack disposed over the flexible substrate region, (c) a transparent upper barrier region that cooperates with the flexible substrate region to encapsulate the OLED stack, thereby protecting it from outside species such as water or oxygen, and (d) a polymeric reinforcement layer having a Young's Modulus ranging from about 0.3 to 7 GPa, which is disposed (i) below the thin substrate region, (ii) above the upper barrier region (in which case it is transparent), or (iii) both below the thin substrate region and above the upper barrier region.

Thin substrate regions are advantageous for use in a variety of applications including, for example, low-profile OLED displays and flexible OLED displays. However, various issues can arise when using thin substrates. For example, when OLED displays that employ metal foils as thin substrates are continuously flexed, for example, into the shape of a cylinder, they will take on a set (i.e., a profile) that reflects the cylindrical curvature and will not return to a completely planar profile when unflexed and placed on a flat surface. In addition, thin metal foils are also easily creased or dented, which can damage, or even destroy, a display. By including a reinforcing layer with the above characteristics however, such issues can be addressed.

These and other aspects, embodiments and advantages of the present invention will become readily apparent to those of ordinary skill in the art upon review of the disclosure to follow.

### BRIEF DESCRIPTION OF THE DRAWINGS

FIGS. 1A and 1B are schematic, cross-sectional views of two typical known OLED structures.

FIG. 2 is a schematic, cross-sectional view of an OLED structure in accordance with an embodiment of a first aspect of the present invention.

FIG. 3 is a schematic, cross-sectional view of an OLED structure in accordance with an embodiment of a second aspect of the present invention.

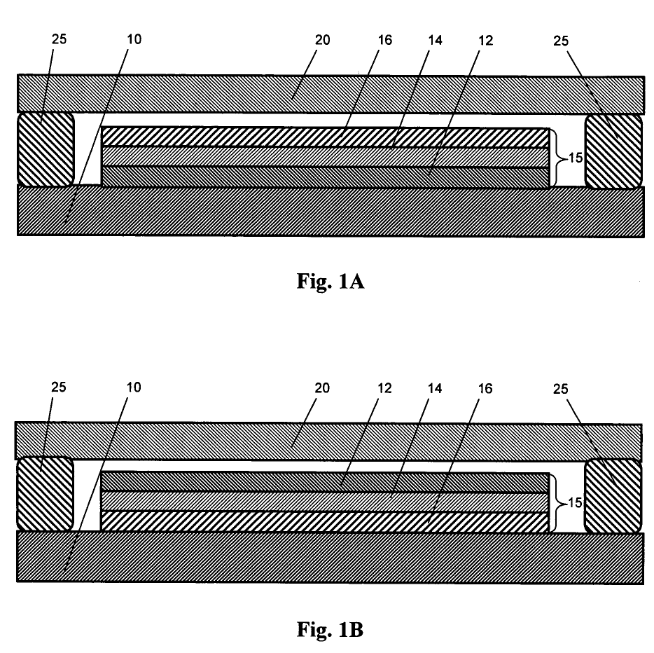

As is typically the case with such figures, the above are simplified schematic representations presented for purposes of illustration only, and the actual structures will differ in numerous respects including the relative scale of the components.

### DETAILED DESCRIPTION OF THE INVENTION

The present invention now will be described more fully hereinafter, in some instances with reference to the accompanying drawings in which certain preferred embodiments of the invention are shown. This invention may, however, be embodied in different forms and should not be construed as limited to the embodiments set forth herein.

As noted above, OLED devices, including the various OLED devices of the present invention, typically include a substrate region, an OLED stack over the substrate region, and an upper barrier region over the OLED stack to protect the OLED stack from environmental species such as water and oxygen. An “OLED stack” includes lower and upper electrodes (i.e., an anode and a cathode) as well as the region (including an organic layer) that is found between the electrodes. As discussed further below, a wide range of OLED stacks are known in the art.

As used herein, a “layer” of a given material includes a region of that material whose thickness is small compared to both its length and width. Examples of layers include sheets, foils, films, laminations, coatings, and so forth. As used herein, a layer need not be planar, but can be bent, folded or otherwise contoured, for example, to at least partially, or even completely, envelop another component. As used herein, a layer can constitute a single region of material, or it can consist of a collection of discrete regions of material (for example, a patterned layer can be provided in the form of a collection of bands).

The organic regions within the OLED stacks of the present invention can be provided in a wide variety of configurations, including the following: (a) a configuration comprising a single organic layer that provides hole transporting, electron transporting and emission functions (i.e., a single layer configuration), (b) a two-layer configuration comprising a hole transport layer and a layer that provides both emission and electron transporting functions (i.e., a single heterostructure configuration), (c) a three-layer configuration comprising a hole transport layer, an emissive layer and an electron transport layer (i.e., a double heterostructure configuration). In each configuration, additional layers may also be present, for example, layers that enhance hole injection or electron injection, or layers that serve to block holes or electrons or excitons. Examples include: (d) a four-layer configuration comprising a hole injection layer, a hole transport layer, an emissive layer, and an electron transport layer, and (e) a five-layer configuration comprising a hole injection layer, a hole transport layer, an emissive layer, a hole blocking layer, and an electron transport layer, and so forth. Several structures for such devices are discussed, for example, in U.S. Pat. No. 5,707,745, the entire disclosure of which is hereby incorporated by reference. Other OLED architecture is also practiced in the art. A wide range of materials are available for making OLED organic regions, and are well known in the art.

Various electrode configurations can be employed within the OLED stacks that are used in conjunction with the present invention, including conventional electrode configurations, where the bottom electrode is an anode and the top electrode is a cathode, and inverted configurations, where the bottom electrode is a cathode and the top electrode is an anode. Depending on the application, the anode may be a transparent or opaque. Where opaque, the anode is reflective in some embodiments. Opaque anode materials include metals such as gold, chromium, magnesium/silver as well as other opaque materials known in the art, while transparent anode materials include metal oxides such as indium tin oxide (ITO), zinc tin oxide as well as other transparent anode materials known in the art. Similarly, the cathode may also be transparent or opaque depending on the application. Where opaque, the cathode is reflective in some embodiments. Opaque cathode materials may include metals such as aluminum, aluminum/lithium, aluminum/lithium fluoride, as well as other opaque cathode materials known in the art, while transparent cathode materials may include metal/metal oxide combinations such as Mg—Ag/ITO, Ca/ITO as well as other as well as other transparent cathode materials known in the art.

By “transparent” is meant that attenuation of radiation as it passes through the region of interest is low, with transmissivities typically greater than 50%, more typically greater than 70%, at the visible wavelength of interest (typically the emission wavelength of the OLED). Conversely, by “opaque” is meant that attenuation of radiation as it passes through the region of interest is high, with transmissivities typically being less than 50%, more typically less than 70%, at the visible wavelength of interest (typically the emission wavelength of the OLED). By “reflective” is meant that the amount of radiation reflected from a surface is high, with reflectivities typically being greater than 50%, more typically greater than 70%, at the visible wavelength of interest (typically the emission wavelength of the OLED).

In the present invention, the substrate region and the upper barrier region typically cooperate to restrict transmission of oxygen, water and other species from the outside environment to the organic region. To assist with the protection from environmental species, a getter material may be provided with the OLED structures of the present invention. The getter material can be essentially any getter material that reacts readily with reactive gases (including water and oxygen), forming stable low-vapor-pressure chemical compounds so as to remove the reactive gases from the gas phase. The getter material is provided to remove reactive gases such as water and oxygen in the event that they penetrate the sealed package, before these gases have the opportunity to cause damage to the OLED region. Desiccants, which are a class of getter material that remove water, are useful for the practice of the present invention. Getter materials include Group IIA metals and metal oxides, such as calcium metal (Ca), barium metal (Ba), barium oxide (BaO) and calcium oxide (CaO).

Depending on the application at hand, the substrate region and the upper barrier region may be opaque or transparent. For traditional bottom-emitting OLED structures, for instance, the substrate region will be transparent, as least in part, while the upper barrier region can be transparent or opaque (and in some instances reflective). For top-emitting OLED structures, the upper barrier region will be transparent, at least in part, while the substrate region can be transparent or opaque (and in some instances reflective). For transparent OLED structures, both the substrate region and the upper barrier region will be transparent, at least in part.

Materials for use in the substrate region include semiconductors, metals, ceramics, polymers, and composite materials. Semiconductors such as silicon offer good barrier properties to water, oxygen and other harmful species and also provide a substrate upon which electronic circuitry can be built. Metals, including metal foils, also offer excellent barrier properties. Preferred metals for substrate formation include single metal materials such as aluminum, gold, nickel and indium, alloys such as nickel alloys and stainless steel, as well as other metals known in the art. Ceramics also offer low permeability, and they provide transparency as well in some cases. Examples of ceramic materials include oxides of transition metals and Group 3A and 4A elements, and include glass as well as other ceramic materials known in the art. Polymers are often preferred as substrate materials where optical transparency and flexibility are desired. Preferred polymers for use in substrates include, for example, polyesters, polyethersulphones, polyimides, polycarbonates and fluorocarbons. Where polymers are used in substrate regions, composite material structures are often employed to improve barrier properties. For example, a composite substrate can be formed by applying a multilayer region containing an alternating series of planarizing material layers and high-density material layers to a flexible substrate material such as a polymeric layer, as described, for example, in U.S. Patent Application 2003/0085652 to Weaver and in U.S. Patent Application 2003/0117068 to Forrest et al. Further discussion of such multilayer regions is provided below. Composite materials are advantageous, for example, in that they can provide transparency and flexibility, while also providing high resistance to transmission of chemical species such as water and oxygen.

As with the substrate regions, the materials selected for the upper barrier region will also depend upon the application at hand and include semiconductors, metals, ceramics, polymers and composites, for example, those discussed above.

In some embodiments, a preformed upper barrier region is bonded to an underlying structure, for example, using a polymer bonding system (e.g., an adhesive) or metallic bonding system (e.g., solder bonding), and so forth.

In other embodiments, an upper barrier region is fabricated over an underlying structure, for instance, via a coating process, such as a deposition process. In some instances, for example, the upper barrier region is a single layer of coated (e.g., deposited) material such as silicon nitride, silicon oxynitride, aluminum oxynitride, or any other material that is impermeable to water and oxygen, including other high-density materials listed below. In other instances, the upper barrier region is a composite region. OLED structures that contain multilayer barrier regions are described, for example, in U.S. Patent Application 2003/0085652 to Weaver and in U.S. Patent Application 2003/0117068 to Forrest et al.

Examples of composite regions that can be formed over an underlying structure are those that comprise a series of cooperative barrier layers, which include (a) one or more layers of planarizing material and (b) one or more layers of high-density material. The composite regions are typically flexible, transparent and have excellent resistance to permeation by water, oxygen and other species. The cooperative barrier layers are preferably provided in an alternating configuration. For example, 1 to 10 pairs of these layers, more preferably 2 to 7 pairs, are commonly used.

By “high-density material” is meant a material with sufficiently close atomic spacing such that diffusion of contaminant and deleterious species, particularly water and oxygen, are hindered. Examples of high-density materials include inorganic materials such as metal oxides, semiconductor oxides, metal nitrides, semiconductor nitrides, metal carbides, semiconductor carbides, metal oxynitrides, semiconductor oxynitrides, and combinations thereof. Specific examples of high-density materials include silicon oxides (SiOₓ), including silicon monoxide (SiO) and silicon dioxide (SiO₂), silicon nitrides (typically Si₃N₄), silicon oxynitrides, aluminum oxides (typically Al₂O₃), aluminum oxynitrides, indium-tin oxides (ITO) and zinc indium tin oxides and combinations thereof. More than one type of high density material can be employed in a given series of cooperative barrier layers. Layers of high-density material can be applied using techniques known in the art such as PECVD methods and PVD methods. PVD methods are processes in which one or more sources of material, typically solid sources, are vaporized at low pressure, and transported to a substrate, upon which a layer of the vaporized material is deposited. The source can be vaporized in a number of ways, including evaporation, sublimation, sputtering, electron-beam impact, and laser ablation. CVD, on the other hand, is a process whereby atoms or molecules are deposited in association with a chemical reaction of vapor-phase precursor species (e.g., a reduction reaction, an oxidation reaction, a decomposition reaction, etc.). When the pressure is less than atmospheric pressure, the CVD process is sometimes referred to as low-pressure CVD or LPCVD. Plasma-enhanced chemical vapor deposition (PECVD) techniques are chemical vapor deposition techniques in which a plasma is employed such that the precursor gas is at least partially ionized, thereby reducing the temperature that is required for chemical reaction.

By “planarizing material” is meant a material that acts to smooth out the irregular contours of the underlying the underlying surface. Examples of planarizing materials include polymers, such as fluorinated polymers, parylenes, cyclotenes and polyacrylates and combinations thereof. More than one type of planarizing material can be employed in a given series of cooperative barrier layers. Layers of such planarizing materials can be provided using techniques known in the art, for example, by dipping, spin coating, sputtering, evaporative coating, spraying, flash evaporation, chemical vapor deposition and so forth. In certain beneficial embodiments of the invention, a layer of monomer (e.g., acrylate containing monomer) is coated (e.g., via a vacuum deposition technique) on the underlying surface and subsequently polymerized by exposure to ultraviolet light.

A first aspect of the invention is directed to top-emitting, high-resolution, OLED structures that comprise the following: (a) a metal foil substrate, (b) a planarization layer disposed over the metal foil substrate, (c) an OLED stack (which includes lower and upper electrodes as well as an organic region disposed between the electrodes), disposed over the planarization layer, and (d) a multilayer barrier region disposed over the OLED stack.

As defined herein, a “high resolution” display is a display with greater than 80 dots per inch (dpi) of size, QVGA (320×240 pixels) or larger.

In operation, light is transmitted upward from the organic region, through the upper electrode and through the multi-layer barrier region. Examples of materials which can be used to form transparent multilayer barrier regions are described above. Examples of transparent electrodes include metal oxide anodes and metal/metal oxide cathodes, and are also described above.

Because, the devices in accordance with this particular aspect of the invention are top-emitting OLED devices, the lower electrode need not be transparent, and can be formed of either transparent or opaque materials. For example, in some embodiments, the lower electrode is formed of a reflective material (e.g., a metal such as gold or chromium), thereby improving the efficiency of the top-emitting device. In other embodiments the lower electrode is formed from a transparent material (e.g., a transparent metal oxide anode or a metal/metal oxide cathode). So long as the lower electrode and planarization layer on the metal foil are transparent, light can be reflected from the underlying foil, which may be highly polished to maximize reflection, if desired.

However, reflection from underlying layers can also be accompanied by a reduction in the apparent display contrast ratio. If desired, one way of reducing reflection and improving contrast ratio is to provide a blackened (e.g., anodized) metal foil substrate. Further information concerning anodized metals can be found, for example, at http://www.alphametal.com/anodizing_notes.htm. Another way to reduce reflection and improve contrast ratio is to provide a low-reflectance absorbing layer over the metal substrate and beneath the OLED device. Examples of such absorbing layers are described, for example, in U.S. Pat. No. 5,986,401 to Thompson et al., which is hereby incorporated by reference in its entirety. In general, the low-reflectance absorbing layer will have a have a high light absorption across the entire visible region of the spectrum so as to produce a gray-to-black surface. However, in some embodiments it will have high absorption only over that part of the spectral region corresponding to the wavelength region generated by the light emitting device. By high light absorption is meant that the absorption of light is at least about 50%, and more typically, about 80-90% or even higher.

In certain embodiments, a thin film transistor (TFT) backplane structure is provided over the foil substrate and beneath the OLED device structure. TFTs are frequently used in forming active matrix displays. In some cases, an absorbing layer like that described above is provided between the metal foil substrate and the TFT backplane, or between the TFT backplane and the OLED device array. The absorbing layer can be for example, a separate layer dedicated to this task. The absorbing layer can also correspond, for example, to the substrate planarization layer itself or it can correspond to the TFT backplane planarization layer. In some embodiments, the absorber layer will be provided with its own planarization layer. Where provided over the TFT backplane, the absorbing layer is capable of reducing reflection from the metal substrate as well as the metallization used in the fabrication of the TFT backplane.

Metal foils for use in conjunction with this aspect of the present invention include single-metal foils such as aluminum foil, gold foil, nickel foil, and indium foil, and alloy foils such as nickel alloy foils and stainless steel foils, as well as other known metal foils. Typically, the metal foils for use in the present invention range from 25 to 250 microns in thickness.

Metal foils have a number of desirable properties, including resistance to shrinkage and distortion, which make them ideal as substrates for the formation of high resolution displays. In this regard, the metal foils that are selected for use in this aspect of the present invention beneficially have a relatively low coefficient of thermal expansion, typically on the order of 20 ppm/° C. or less. Examples of such foils include series 301, 304, 430, and 410 stainless steel foils, and Havar foils.

Although thin, metal foils can nonetheless be quite strong. Metal foils for use in conjunction with the present invention routinely have yield and tensile strengths of 200 MPa or greater, 400 MPa or greater, 800 MPa or greater, 1600 MPa or even more, without undergoing irreversible deformation or fracture.

Additional desirable properties of metal foils include the following, among others: (1) they have outstanding barrier properties and thus protect the overlying OLED stack from oxygen, moisture and other chemical species; (2) metal foils can withstand high temperature processing, which is frequently employed, for example, in the formation of TFTs for use in active matrix displays; (3) some metal foils are magnetic or are paramagnetic, which is potentially advantageous in processing (e.g., allowing the foil to be held flat during processing, or allowing it to be heated by magnetic coupling) and in product use; (4) metal foil substrates are typically much thinner that plastic or glass substrates, for example, reducing the profile of the finished device; (5) metal foil is a good heat conductor, aiding in heat dissipation; (6) metal foil is a good electrical conductor, allowing it to be used, for example, as a ground plane; (7) metal foil requires far less outgassing than plastic substrates, reducing production times; and (8) metal foils are flexible.

The planarization layer use in conjunction with this aspect of the invention is typically less than 10 microns in thickness, and more typically ranges from 0.1 to 7.5 microns in thickness, and even more typically from 1 to 5 microns in thickness. The planarization layer used in conjunction with this aspect of the invention is typically a polymeric planarization layer.

The planarization layer can be established on the metal foil using any of a wide variety of techniques including coating by chemical vapor deposition (CVD), coating by physical vapor deposition (PVD), and coating by processes in which a liquid precursor is applied to the metal foil, followed by solidification of the same (e.g., thermoplastic processing, application of a curable system, and solution coating). PVD and CVD processes are described above. In thermoplastic processing, a polymer (or polymer blend) is heated until it forms a melt, whereupon it is applied to the substrate in liquid form and then cooled, thereby returning the polymer melt back to a solid state. Where curable systems are employed, a curable precursor material is applied to the substrate in liquid form. It is then cured, for example, by the application of radiation, such as ultraviolet radiation, which results in chemical reactions within the applied layer (e.g., polymerization, crosslinking, etc.), thereby resulting in a solid polymeric layer. In solution processing, one or more polymers making up the ultraviolet protective region are dissolved in a solvent system and applied to the substrate, solvent is then removed, resulting in a solid polymeric layer. Because these techniques involve application of a fluid to a substrate, various application techniques can be used, including, for example, spin coating, web coating, spraying, dipping, and ink jet application techniques.

The planarization layer can also be established on the metal foil using lamination techniques, in which a preformed planarization layer is bonded to the metal foil. Bonding can proceed, for example, by using an adhesive, such as a pressure sensitive adhesive, a melt adhesive or a curable adhesive.

Analogous to the layers of planarizing material that are used to form the above-described multilayer barrier regions, the materials that are selected for the planarization layer act to smooth out the irregular contours of the underlying metal foil. The fact that many techniques are available for application of the planarization layer increases the number of polymers that can be used for this purpose. The planarization layer will generally be formed from one or more polymers (i.e., from a single polymer or a polymer blend), which can be selected from natural and synthetic homopolymers and copolymers (including alternating, random, tapered, statistical, gradient and block copolymers) having a variety of architectures (e.g., cyclic, linear or branched architectures). Polymers for use in such layers include fluorinated polymers, parylenes, cyclotenes and polyacrylates, among many others. Where a polymeric planarization layer is provided, it will typically contain anywhere from 75 to 100 wt % polymer(s), more typically from 95-100 wt %.

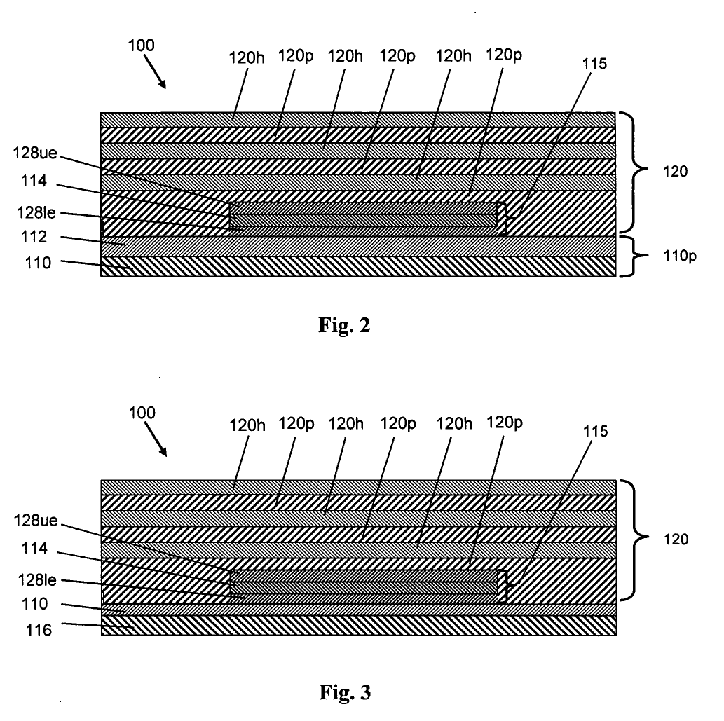

An example of a structure that contains a planarization layer is schematically illustrated (in cross-sectional view) in FIG. 2, in accordance with one specific embodiment of this first aspect of the invention. Referring now to FIG. 2, an OLED structure 100 is illustrated, which includes a planarized metal foil substrate 110p containing a planarization layer 112 disposed on a metal foil substrate 110. An OLED stack 115 is disposed on the planarized metal foil substrate 110p. The OLED stack 115 in this particular illustration includes an organic region 114 disposed between a transparent upper electrode 128ue and a lower electrode 1281e, one of which is an anode and the other of which is a cathode. Many OLED architectures are known which can be used between the electrodes 1281e, 128ue of the OLED stack 115. A multilayer barrier region 120, formed from alternating layers of high density material 120h and planarizing material 120p, is provided over the OLED stack 115. The multilayer barrier region 120 cooperates with the planarized metal foil substrate 110p to encapsulate the OLED stack 115. In the embodiment shown, a layer of planarizing material 120h is deposited first, although a layer of high density material may also be so deposited. Also, three layers of high density material 120h and three layers of planarizing material 120p are used, but the number of these layers can obviously vary.

As is typical in the OLED art, OLED device structures in accordance with this aspect of the invention are typically built from the substrate up. For example, an OLED stack 115 can first be deposited on the planarized substrate 110p using methods known in the art. Subsequently, a multilayer barrier region 120 is provided over the ultraviolet protective region, also using techniques known in the art.

Depending upon the materials selected, the various OLED structures described in conjunction with this first aspect of the invention herein can be either flexible or inflexible. As used herein “flexible” means conformable or capable of repetitive flexing around objects with at least one radius of curvature of less than or equal to approximately 25 cm. An “inflexible” OLED structure is one that is not flexible.

A second aspect of the present invention addresses problems that can arise when using thin substrates, including thin metal and polymeric substrates. As used herein, a “thin substrate” is a substrate having a thickness that is less than 200 microns. Various metal and polymeric materials that are suitable for use as substrates are described above.

Thin substrates are advantageous for use in a variety of applications including, for example, the fabrication of low-profile OLED displays and flexible OLED displays. However, various issues can arise when using thin substrates. For example, when OLED displays that employ metal foils as substrates are continuously flexed, for example, into the shape of a cylinder, they will take on a set (i.e., a profile) that reflects the cylindrical curvature and will not return to a completely planar profile when unflexed and placed on a flat surface. In addition, metal foils are also easily creased or dented, which can damage, or even destroy, a display.

To address these and other challenges, and in accordance with a second aspect of the invention, a flexible, top emitting OLED structure is provided, which contains the following: (a) thin substrate region, (b) an OLED stack (which includes lower and upper electrodes, and an organic region disposed between the electrodes) disposed over the flexible substrate region, (c) a transparent upper barrier region that cooperates with the flexible substrate region to encapsulate the OLED stack, thereby protecting it from outside species such as water or oxygen, and (d) a polymeric reinforcement layer that is disposed (i) below the substrate region, (ii) above the upper barrier region (in which case it is transparent), or (iii) both below the substrate region and above the upper barrier region.

Adding the polymeric reinforcement layer to the OLED structure improves the mechanical ruggedness of the structure. For example, once attached, the reinforcement layer adds structural support to the device structure, stiffening the device structure. Moreover, when disposed under the substrate region, the reinforcement layer protects the substrate region from being scratched, punctured, creased, dented and so forth. On the other hand, when the reinforcement layer is disposed over the upper barrier region, it protects the upper barrier from being scratched, punctured, and so forth. The reinforcement layer may also serve to flatten OLED structures which would otherwise not lie flat, including OLED structures having metal foil substrates which have a tendency to take on a curvature when continuously flexed. This is important, for example, where the OLED is folded or rolled into a cylinder for storage and then unfolded or flattened for viewing. Where the reinforcement layer is applied to the substrate early on in the manufacturing process, the dimensional stability provided by the reinforcement layer makes the flexible OLED structure easier to work with during processing.

In operation, light is transmitted upward from the organic region, through the upper electrode and through the upper barrier region. Hence, the upper electrode and the upper barrier region are both transparent in this aspect of the invention. Examples of transparent electrodes are described above and include metal oxide anodes, such as ITO, and metal/metal oxide cathodes, such as Mg—Ag/ITO or Ca/ITO. A variety of materials can also be used to form the transparent upper barrier, including flexible glass barriers (available, for example, from Schott Glass Technologies) and flexible polymer layers. In certain preferred embodiments, the transparent upper barrier is a multilayer barrier region such as those described above.

Because the device is a top-emitting OLED device, the lower electrode need not be transparent, and can be formed of either transparent or opaque materials. For example, in some embodiments, the lower electrode is formed of a reflective material (e.g., a metal such as gold or chromium), thereby improving the efficiency of the top-emitting device. In other embodiments the lower electrode is formed from a transparent material (e.g., a transparent metal oxide anode or metal/metal oxide cathode). So long as any layer(s) intervening between the lower electrode and the substrate are transparent, light can be reflected from the underlying substrate, which may be, for example, highly polished foil. As noted above, reflection from underlying layers can be accompanied by a reduction in the apparent display contrast ratio. Consequently, it may be desirable in some embodiment reduce reflection, for example, by adding a low-reflectance absorbing layer over the metal substrate and beneath the OLED device, or by providing a blackened (e.g., anodized) metal foil.

As noted above, the thin substrate can be made from a variety of materials including various suitable metallic, polymeric, and composite substrate materials. Metal foils are particularly beneficial for this second aspect of the inventions, as they have many desirable properties, such as those previously discussed. Examples of metal foils include single-metal foils such as aluminum foil, gold foil, nickel foil, and indium foil, and alloy foils such as nickel alloy foils and stainless steel foils, as well as other known metal foils. Typically, the metal foils for use in this aspect of the present invention range from 50 to 200 microns in thickness.

As previously noted, the polymeric reinforcement layer is positioned either above the transparent upper barrier region, below the substrate region, or both. Where positioned below the substrate, it can be transparent or opaque. Where positioned above the upper barrier, the polymeric reinforcement layer is transparent and in some embodiments, optionally absorbs ultraviolet light. As noted previously, the reinforcement layer provides a number of useful functions, including providing mechanical protection and dimensional stability. Furthermore, the reinforcement layer can also be designed to provide additional protection from environmental species that are harmful to sensitive OLED components.

The polymeric reinforcement layer can be established on an adjacent layer using a variety of techniques, several of which are discussed herein, including coating by chemical vapor deposition (CVD), coating by physical vapor deposition (PVD), and coating by processes in which a liquid precursor is applied to the metal foil, followed by solidification of the same (e.g., thermoplastic processing, application of a curable system, and solution coating).

The polymeric reinforcement layer can also be laminated or otherwise bonded to either or both surfaces of the OLED structure. For example, the reinforcement layer can be applied to the adjacent layer with the assistance of an adhesive, such as a pressure sensitive adhesive, a melt adhesive or a curable adhesive.

The polymeric reinforcement layer can be applied to an adjacent layer at a variety of points in the manufacturing process. For example, the reinforcement layer can be applied to one side of a metal foil substrate before further layers (e.g., a planarization layer, an OLED stack and an upper multilayer composite barrier) are applied to the substrate. In other embodiments, the reinforcement layer is applied to either side of the OLED device subsequent to the application of these layers.

The polymeric reinforcement layer for use in this aspect of the present invention typically has a Young's Modulus ranging from about 0.3 to 7 GPa, more typically from about 2 to 5.5 GPa. Various materials are available which meet these criteria including certain polyesters, polyethersulphones, polyimides, polycarbonates and fluorocarbons. The polymeric reinforcement layer will typically contain from 75-100 wt % polymer(s), more typically from 95-100 wt %.

Typical thicknesses for the polymeric reinforcement layer are from 20 to 400 microns, more typically 50 to 200 microns. The polymeric reinforcement layer may include multiple sub-layers in which the sub-layers cooperate to provide dimensional stability and protection.

As above, the various OLED structures described in conjunction with this second aspect of the invention can include a thin film transistor (TFT) structure, which is provided over the substrate and beneath the OLED stack. Moreover, the OLED structures described in conjunction with this second aspect of the invention are high-resolution OLED structures in some embodiments.

An example of a structure that contains a polymeric reinforcement layer is schematically illustrated (in cross-sectional view) in FIG. 3, in accordance with one specific embodiment of the invention. Referring now to FIG. 3, an OLED structure 100 is illustrated, which includes a thin substrate region 110 (e.g., a metal foil), over which is disposed an OLED stack 115. Where the OLED stack 115 is built upon a metal foil substrate region 110, it may be beneficial to provide a planarization layer (not illustrated) between the substrate region 110 and the OLED stack 115, as described above in conjunction with the first aspect of the invention. The OLED stack 115 in this particular embodiment includes an organic region 114 disposed between a transparent upper electrode 128ue and a lower electrode 1281e, although many other OLED stack architectures known in the OLED can be used. A transparent upper barrier region 120, in this particular embodiment, a multilayer barrier region formed from alternating layers of high density material 120h and planarizing material 120p, is provided over the OLED stack 115. In the embodiment shown, a layer of planarizing material 120h is first deposited, although a layer of high density material may also be deposited first. Also, three layers of high density material 120h and three layers of planarizing material 120p are used, but the number of these layers can obviously vary. The barrier region 120 cooperates with the substrate region 110 to encapsulate the OLED stack 115. A polymeric reinforcement layer 116 is also illustrated in FIG. 4, which in this particular embodiment is provided below the substrate region 110.

As is common in OLED construction, OLED device structures in accordance with this aspect of the invention are typically built from the substrate up. For example, an OLED stack 115 can first be deposited on the substrate region 110 using methods known in the art. Subsequently, multilayer barrier region 120 is provided over the ultraviolet protective region, also using techniques known in the art. Finally, the polymeric reinforcement layer 116 is applied to the substrate region 110 using techniques such as those described hereinabove. Alternatively, the polymeric reinforcement layer 116 can be applied to the substrate region 110 prior to deposition of the OLED stack.

Although the present invention has been described with respect to several exemplary embodiments, there are many other variations of the above-described embodiments that will be apparent to those of ordinary skill in the art. It is understood that these variations are within the teachings of the present invention, and that the invention is to be limited only by the claims appended hereto.

1. An OLED device structure comprising: (a) a metal foil layer, (b) a first planarization layer disposed over said metal foil layer, said first planarization layer ranging between 0.1 and 7.5 microns in thickness, (c) an OLED stack disposed over said planarization layer, said OLED stack comprising a lower electrode, an upper transparent electrode, and an organic region disposed between the lower and upper electrodes, and (d) a transparent multilayer barrier region disposed over said OLED stack, wherein said OLED device structure is a top-emitting, high-resolution OLED structure.

2. The OLED device structure of claim 1, wherein said OLED device structure is a flexible OLED device structure.

3. The OLED device structure of claim 1, wherein said upper electrode is transparent cathode.

4. The OLED device structure of claim 1, wherein said transparent multilayer barrier region comprises at least two pairs of alternating high-density layers and planarizing layers, which high-density layers may be the same or different from each other and which planarizing layers may be the same or different from each other.

5. The OLED device structure of claim 4, wherein at least one of said planarizing layers comprises a material selected from fluorinated polymers, parylenes, perylenes, cyclotenes and polyacrylates.

6. The OLED device structure of claim 4, wherein at least one of said planarizing layers comprises an ultraviolet-radiation polymerized polymer.

7. The OLED device structure of claim 4, wherein at least one of said high-density layers comprises a material selected from metals, metal oxides, metal nitrides, metal carbides, metal oxynitrides, semiconductor oxides, semiconductor nitrides, semiconductor carbides and semiconductor oxynitrides.

8. The OLED device structure of claim 1, wherein said metal foil layer is selected from series 301 stainless steel foils, series 304 stainless steel foils, series 430 stainless steel foils, and series 410 stainless steel foils.

9. The OLED device structure of claim 1, wherein said metal foil layer has a coefficient of thermal expansion of 20 ppm/° C. or less.

10. The OLED device structure of claim 1, wherein said first planarization layer comprises a polymer selected from fluorinated polymers, parylenes, cyclotenes and polyacrylates.

11. The OLED device structure of claim 1, wherein said first planarization layer is coated on said metal foil layer by a vapor deposition technique.

12. The OLED device structure of claim 1, wherein said first planarization layer is coated on said metal foil layer by first applying a precursor layer in liquid form, followed by solidification of said precursor layer.

13. The OLED device structure of claim 1, wherein said first planarization layer ranges between 1 and 5 microns in thickness.

14. The OLED device structure of claim 1, further comprising a thin film transistor region between said substrate and said OLED stack.

15. The OLED device structure of claim 1, further comprising an absorbing layer between said metal foil layer and said OLED stack.

16. The OLED device structure of claim 1, wherein said first planarization layer is an absorbing layer.

17. The OLED device structure of claim 14, further comprising an absorbing layer that is positioned (a) between said metal foil layer and said thin film transistor region or (b) between said thin film transistor region and said OLED stack.

18. The OLED device structure of claim 17, wherein said absorbing layer is positioned between said thin film transistor region and said OLED stack, and wherein said absorbing layer functions as an additional planarization layer.

19. The OLED device structure of claim 1, wherein said metal foil layer is an anodized metal foil layer.

20. An OLED device structure comprising: (a) a thin substrate region having a thickness that is 200 microns or less, (b) an OLED stack disposed over said thin substrate region, said OLED stack comprising a lower electrode, an upper transparent electrode, and an organic region disposed between the lower and upper electrodes, (c) a transparent upper barrier region disposed over said OLED stack, and (d) one or more polymeric reinforcement layers disposed below the substrate region, above the upper barrier region, or both below the substrate region and above the upper barrier region, wherein at least one of said one or more polymeric reinforcement layers has a Young's Modulus ranging from about 0.3 to 7 GPa, and wherein said OLED device structure is a flexible, top-emitting OLED device structure.

21. The OLED device structure of claim 20, wherein said thin substrate region comprises a polymeric layer.

22. The OLED device structure of claim 20, wherein said thin substrate region comprises a metal foil layer.

23. The OLED device structure of claim 3, wherein a polymeric planarization layer ranging from 0.1 to 7.5 microns in thickness is provided between said metal foil and said OLED stack.

24. The OLED device structure of claim 3, wherein said OLED device structure is a high-resolution OLED structure.

25. The OLED device structure of claim 20, wherein said upper electrode is a cathode.

26. The OLED device structure of claim 20, wherein said transparent upper barrier region is a transparent multilayer barrier region.

27. The OLED device structure of claim 26, wherein said transparent multilayer barrier region comprises at least two pairs of alternating high-density layers and planarizing layers, which high-density layers may be the same or different from each other and which planarizing layers may be the same or different from each other.

28. The OLED device structure of claim 27, wherein at least one of said planarizing layers comprises a material selected from fluorinated polymers, parylenes, perylenes, cyclotenes and polyacrylates.

29. The OLED device structure of claim 27, wherein at least one of said high-density layers comprises a material selected from metals, metal oxides, metal nitrides, metal carbides, metal oxynitrides, semiconductor oxides, semiconductor nitrides, semiconductor carbides and semiconductor oxynitrides.

30. The OLED device structure of claim 20, wherein said device structure comprises a polymeric reinforcement layer disposed below the substrate region.

31. The OLED device structure of claim 30, wherein said polymeric reinforcement layer disposed below the substrate region is laminated to said substrate region.

32. The OLED device structure of claim 30, wherein said polymeric reinforcement layer disposed below the substrate region is joined to said substrate region by an adhesive.

33. The OLED device structure of claim 30, wherein said polymeric reinforcement layer disposed below the substrate region is coated on said substrate region by a coating process.

34. The OLED device structure of claim 20, wherein said device structure comprises a polymeric reinforcement layer disposed above the upper barrier region.

35. The OLED device structure of claim 34, wherein said polymeric reinforcement layer disposed above the upper barrier region is laminated to said upper barrier region.

36. The OLED device structure of claim 34, wherein said polymeric reinforcement layer disposed above the upper barrier region is joined to said upper barrier region by an adhesive.

37. The OLED device structure of claim 34, wherein said polymeric reinforcement layer disposed above the upper barrier region coated on said upper barrier region.

38. The OLED device structure of claim 20, wherein said device structure comprises a polymeric reinforcement layer disposed below the substrate region and a polymeric reinforcement layer disposed above the upper barrier region.

39. The OLED device structure of claim 20, wherein said device structure comprises a polymeric reinforcement layer that comprises a polymer selected from polyesters, polyethersulphones, polyimides, polycarbonates and fluorocarbons.

40. The OLED device structure of claim 20, wherein said device structure comprises a polymeric reinforcement layer that ranges from 20 to 400 microns in thickness.

41. The OLED device structure of claim 20, wherein said device structure comprises a polymeric reinforcement layer that ranges from 50 to 200 microns in thickness.

42. The OLED device structure of claim 20, wherein said device structure comprises a polymeric reinforcement layer that has a Young's Modulus ranging from 2 to 5.5 GPa.

43. The OLED device structure of claim 20, further comprising a thin film transistor region between said substrate and OLED stack.
